(19) United States
(12) Patent Application Publication
(10) Pub. No.: US 2024/0372027 A1
(43) Pub. Date: Nov. 7, 2024

(54) High-Power Photodiode Structure and Related Methods of Manufacture

(71) Applicant: Phase Sensitive Innovations, Inc., Newark, DE (US)

(72) Inventors: Matthew Konkol, Newark, DE (US); Victoria Carey, Newark, DE (US); Peng Yao, Newark, DE (US); Dennis Prather, Newark, DE (US)

(21) Appl. No.: 18/649,656

(22) Filed: Apr. 29, 2024

Related U.S. Application Data
(60) Provisional application No. 63/462,899, filed on Apr. 28, 2023.

(51) Int. Cl. H01L 31/109; H01L 31/024; H01L 31/0304; H01L 31/0352; H01L 31/18; H01P 3/00

(52) U.S. Cl. CPC H01L 31/109; H01L 31/024; H01L 31/03046; H01L 31/03529; H01L 31/1844; H01P 3/003

(57) ABSTRACT

A charge-compensated modified uni-traveling carrier (CC-MUTC) photodiode comprising a semiconductor substrate and a stack of functional layers including a p-contact layer stacked on and in contact with the semiconductor substrate, an absorber layer stacked on the p-contact layer, a cliff layer stacked on the absorber layer, a drift layer stacked on the cliff layer, and an n-contact layer stacked on the drift layer. The CC-MUTC photodiode further comprises a first metal contact in contact with the p-contact layer and a second metal contact in contact with the n-contact layer.

### CROSS-REFERENCE TO RELATED APPLICATION

This application is a non-provisional application of Provisional Application No. 63/462,899 filed Apr. 28, 2023, the entire content of which is hereby incorporated by reference.

### TECHNICAL FIELD

This disclosure relates generally to a novel photodiode and a novel method of manufacturing a photodiode.

### BACKGROUND

High power photodiode applications continue to be developed to provide novel solutions to address various challenges. For example, antenna arrays being driven by high power photodiodes are being developed. However, to power various systems to a desired level, the power applied to a photodiode should be increased. For example, a light beam (e.g., laser light) may be modulated and used to drive a photodiode, with the photodiode converting the light to an RF electrical signal (e.g., to drive a corresponding RF antenna). However, heat is quickly generated by the photodiode in such an operation. Without efficient heat dissipation, problems associated with thermal failure or saturation due to over-heating may occur.

A charge-compensated modified uni-traveling carrier (CC-MUTC) photodiode is designed to promote high power conversion efficiency (“High-Saturation-Current Modified Uni-Traveling-Carrier Photodiode with Cliff Layer,” by Li et al (IEEE J. Quantum Electron., Vol. 46, No. 5, May 2010)). In a CC-MUTC photodiode, epitaxy (i.e., epitaxial structure) is optimized for high-power radio frequency (RF) generation, which is essential for high-gain, low-noise links, which are the basis for a rapidly growing RF photonic application space. As shown in FIG. 1, an example structure of a CC-MUTC photodiode comprises an indium gallium arsenide (InGaAs) absorber layer optimized for 1550 nm optical wavelength back-illumination and an indium phosphide (InP) drift layer.

Specifically, the example structure of a CC-MUTC photodiode illustrated in FIG. 1 includes a InP semi-insulating substrate having an n-contact layer comprising n+ InP and n+ InGaAs; a drift layer comprising n− InP layer; a cliff layer comprising n InP; a first quaternary layer comprising n− InGaAsP; a depleted absorber layer comprising n− InGaAs; an undepleted absorber layer comprising p InGaAs and p+ InGaAs; a second quaternary layer comprising p− InGaAsP; an electron blocking layer comprising p+ InP; and a p-contact layer comprising p+ InGaAs sequentially stacked thereon. The depleted absorber layer and the undepleted absorber layer may be collectively referred to herein as the “absorber layer.” While this embodiment consists of III-V materials, i.e., InGaAs absorber layer and InP drift layer, optimized for telecom operation, a CC-MUTC photodiode may be designed using an analogous combination of semiconductor materials that satisfy the following one or more design parameters: (1) The absorber layer is primarily p-doped (i.e., the device is uni-traveling carrier); (2) The absorber layer is partially depleted, and with gradient doping to achieve a quasi-electric field which aids in electron transport; (3) The drift layer is transparent, which allows for increased responsivity in the back-illuminated orientation due to optical reflection of unabsorbed incident light back into the absorber layer from the top metallic ohmic contact; (4) The device is charge-compensated in the sense that the internal electric field is pre-distorted to mitigate electric field collapse within the photodiode during high-power operation; and (5) The device is modified with a cliff layer and a quaternary compound (e.g., indium gallium arsenide phosphide (InGaAsP)) forming crystal lattice transition layers (i.e., quaternary layers) to mitigate electric field discontinuities at the absorber layer-drift layer heterojunction interface.

Because of these epitaxial design choices, the dissipated power at failure of CC-MUTC photodiodes is only limited by thermal failure. As such, record high-power photodiode results have been measured after flip-chip bonding CC-MUTC photodiodes to a heat sink (e.g., a high-thermal conductivity submount substrate), as illustrated in FIG. 2, for example, which are used to improve heat flow out of the photodiode's active region. Typically, the flip-chip bonding is based on the formation of high-thermal conductivity gold-gold thermo-compression bonds between electrodes patterned on both the photodiode and submount substrate. A variety of high-thermal conductivity substrates have been leveraged for achieving high-power results, including, but not limited to silicon (Si), aluminum nitride (AlN), and diamond. Counterintuitively however, the power handling performance improvement of a CC-MUTC photodiode is not a strong function of the thermal conductivity of the submount substrate. As illustrated in Table 1 below, diamond may have ten times greater thermal conductivity than AlN. However, despite this fact, CC-MUTC photodiodes flip-chip bonded to diamond submount substrates dissipate only 50% more power at failure than those flip-chip bonded to AlN submount substrates.

TABLE 1
List of thermal conductivities.

| Material | $Thermal conductivity ( \frac{W}{m \cdot K} )$ |
|---|---|
| Aluminum nitride (AIN) [polycrystalline] | 170-230 |
| Diamond [single crystal] | >2000 |
| Gold (Au) | 300 |
| Indium gallium arsenide (InGaAs) | 5 |
| Indium gallium arsenide phosphide | 5 |
| (InGaAsP) | |
| Indium phosphide (InP) | 80 |
| Silicon (Si) | 150 |

### SUMMARY

A charge-compensated modified uni-traveling carrier (CC-MUTC) photodiode comprising a semiconductor substrate and a stack of functional layers including a p-contact layer stacked on and in contact with the semiconductor substrate, an absorber layer stacked on the p-contact layer, a cliff layer stacked on the absorber layer, a drift layer stacked on the cliff layer, and an n-contact layer stacked on the drift layer. The CC-MUTC photodiode further comprises a first metal contact in contact with the p-contact layer and a second metal contact in contact with the n-contact layer.

A flip-chip bonded charge-compensated modified uni-traveling carrier (CC-MUTC) photodiode comprising a semiconductor substrate and a stack of functional layers, including a p-contact layer stacked on and in contact with the semiconductor substrate, an absorber layer stacked on the p-contact layer, a cliff layer stacked on the absorber layer, a drift layer stacked on the cliff layer, an n-contact layer stacked on the drift layer. The CC-MUTC photodiode further comprises a heat sink on the stack of function layers, wherein the n-contact layer is disposed closer to the heat sink than the p-contact layer.

A method of manufacturing a charge-compensated modified uni-traveling carrier (CC-MUTC) photodiode comprising forming a stack of functional layers onto a semiconductor substrate. The functional layers including a p-contact layer stacked on and in contact with the semiconductor substrate; an absorber layer stacked on the p-contact layer; a cliff layer stacked on the absorber layer; a drift layer stacked on the cliff layer; an n-contact layer stacked on the drift layer. The method further comprises connecting a first metal contact to the p-contact layer and connecting a second metal contact to the n-contact layer.

### BRIEF DESCRIPTION OF THE DRAWINGS

The above and other objects, features, and advantages of the inventive concept will become more apparent to those skilled in the art upon consideration of the following detailed description with reference to the accompanying drawings.

FIG. 1 illustrates a conventional epitaxial structure of CC-MUTC photodiode;

FIG. 2 illustrates a cross-sectional view of a conventional flip-bonded structure utilizing the CC-MUTC photodiode illustrated in FIG. 1;

FIG. 3 illustrates a graph showing different heat sources in the CC flip-bonded structure illustrated in FIG. 2, which utilizes the CC-MUTC photodiode illustrated in FIG. 1;

FIG. 4 illustrates an epitaxial structure of a flipped CC-MUTC photodiode according to example embodiments;

FIGS. 5A and 5B illustrate internal electric fields and bandgap diagrams of a MUTC with a cliff layer and a MUTC without a cliff layer;

FIG. 6 illustrates a cross-sectional view of a flip-bonded structure utilizing the flipped CC-photodiode illustrated in FIG. 4 according to example embodiments;

FIG. 7 illustrates an epitaxial structure of a flipped CC-MUTC photodiode according to example embodiments; and

FIG. 8 illustrates an epitaxial structure of a flipped CC-MUTC photodiode according to example embodiments.

### DETAILED DESCRIPTION

The present disclosure now will be described more fully hereinafter with reference to the accompanying drawings, in which various exemplary implementations are shown. The invention may, however, be embodied in many different forms and should not be construed as limited to the exemplary implementations set forth herein. These exemplary implementations are just that—examples—and many implementations and variations are possible that do not require the details provided herein. It should also be emphasized that the disclosure provides details of alternative examples, but such listing of alternatives is not exhaustive. Furthermore, any consistency of detail between various examples should not be interpreted as requiring such detail—it is impracticable to list every possible variation for every feature described herein. The language of the claims should be referenced in determining the requirements of the invention.

In the drawings, the size and relative sizes of layers and regions may be exaggerated for clarity. Like numbers refer to like elements throughout. As used herein, the term “and/or” includes any and all combinations of one or more of the associated listed items and may be abbreviated as “/”.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Novel aspects of the inventive concept described herein are based on the results of an heat analysis of conventional CC-MUTC photodiodes conducted by the inventors (“Thermal Dissipation Enhancement in Flip-Chip Bonded Uni-Traveling carrier Photodiodes,” by Bai et al (Opt. Lett., Vol. 48, No. 19, October 2023, herein incorporated by reference in its entirety)). Conclusions discovered by the inventors, through the analysis of the results of the heat analysis, explained the phenomenon discussed above in which, despite the fact that diamond has more than ten times greater thermal conductivity than AlN, CC-MUTC photodiodes flip-chip bonded to diamond submount substrates dissipate only 50% more power at failure than those flip-chip bonded to AlN submounts. First, near the thermal failure point of CC-MUTC photodiodes, most of the heat is generated in the intrinsic region (i.e., the drift layer) of the CC-MUTC photodiode. This is due to joule heating which has a magnitude of:

$${P}_{( joule , internal )} = {I}_{ph} {V}_{bias} . \qquad ( Formula 1 )$$

Where Iₚₕ is the DC photocurrent and V_{bias} is the bias voltage. In general, the bias voltage should be on the order of IₚₕR_{load}, where R_{load}=50 Ω in most cases. Heat is also generated due to the optical input power and contact resistance. This heat is generated in the InGaAs absorber and at the metal-semiconductor interfaces, respectively.

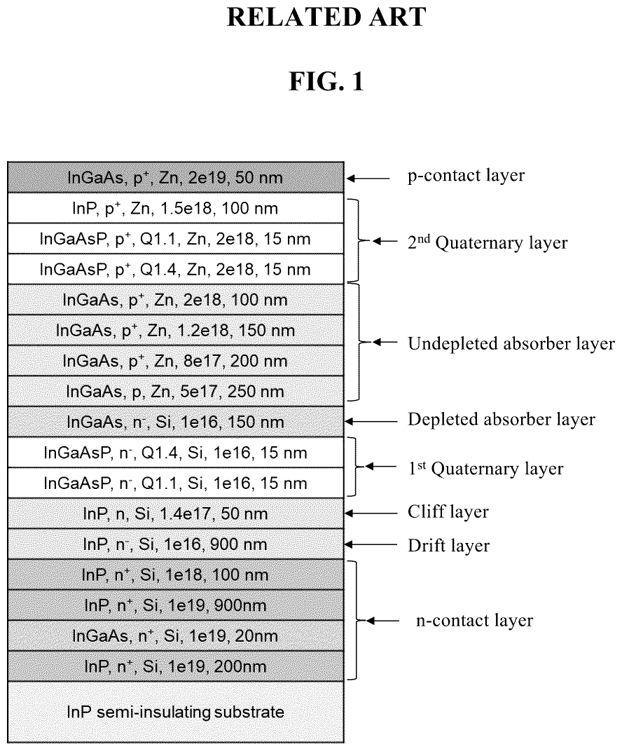

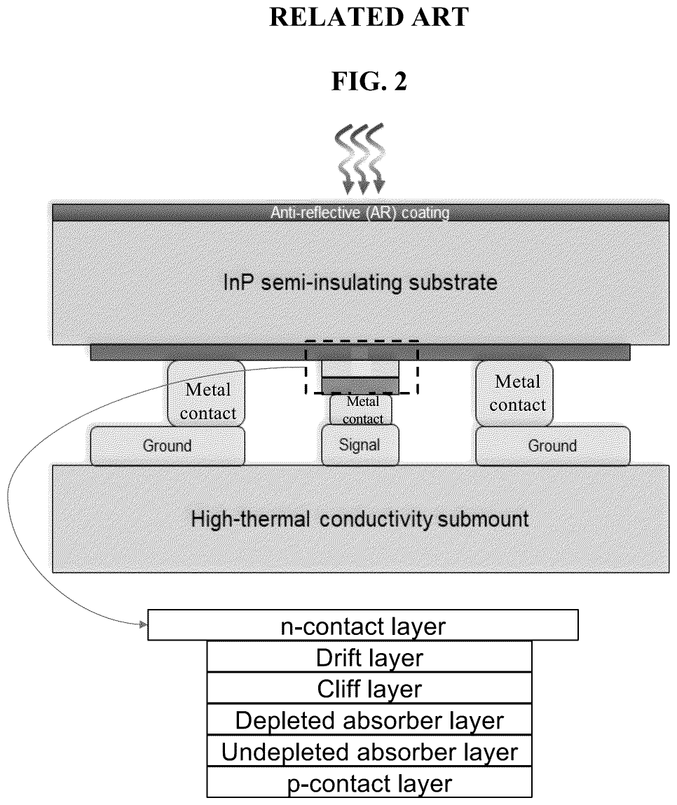

FIG. 2 illustrates a cross-sectional view of a conventional back-illuminated double-mesa flip-bonded structure utilizing the CC-MUTC photodiode illustrated in FIG. 1. As illustrated in FIG. 2, the CC-MUTC photodiode has been flipped such that the p-contact layer faces a heat sink (e.g., a high-thermal-conductivity submount, such as a diamond submount substrate, or a SiC submount substrate) and the CC-MUTC photodiode is then bonded to the heat sink. As illustrated in FIG. 2, the bonded structure is in the form of a mesa structure with an anti-reflecting (AR) coating formed on the InP semi-insulating substrate.

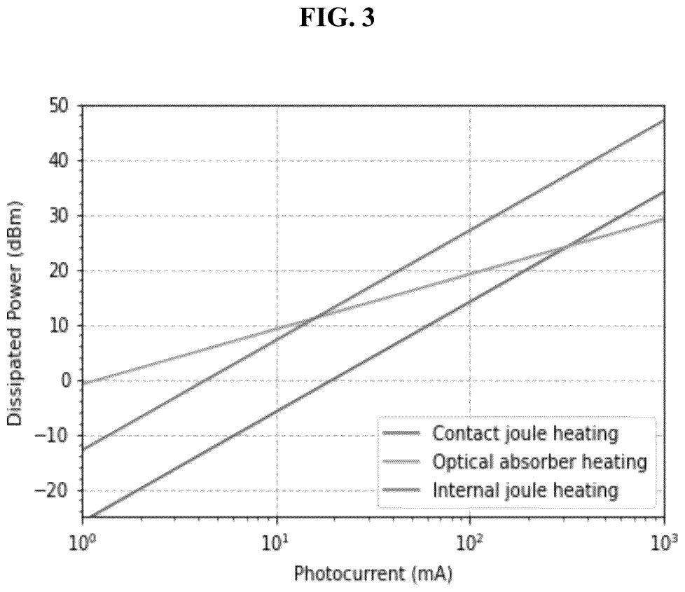

Aspects of the results of the thermal analysis conducted by the inventors are shown in FIG. 3 as a graphical representation of different heat sources in the CC-MUTC flip-bonded structure illustrated in FIG. 2, which utilizes the conventional CC-MUTC photodiode illustrated in FIG. 1. As shown in FIG. 3, given sufficiently high photocurrent, a clear majority of the heat is due to internal joule heating which is generated within the drift layer and the absorber layers of the CC-MUTC photodiode. Moreover, the thermal analysis conducted by the inventors demonstrated that, because InGaAs has a very low thermal conductivity (see Table 1), it acts as a thermal barrier to thereby significantly block the transfer of heat from the drift layer and absorber layer to the high-thermal conductivity submount substrate where the heat is intended to dissipate. Due to this highly impeded flow of heat through the CC-MUTC photodiode in the direction toward the submount substrate, the thermal conductivity of the submount substrate is not able to be leveraged with high efficiency. Thus, it can be concluded that CC-MUTC photodiode power handling is not a strong function of the submount's thermal conductivity.

As a CC-MUTC is thermally limited (i.e., its operation is limited only by a corresponding maximum operational temperature), there has been much interest in heat removal from the CC-MUTC (to keep the CC-MUTC from overheating) to allow operating the CC-MUTC at higher power levels (and to therefore generate and output electrical signals at higher power levels). Previously published thermal analysis (e.g., “Improved Power Conversion Efficiency in High-Performance Photodiodes by Flip-Chip Bonding on Diamond,” by Xie et al. (Optica, Vol. 1, No. 6, December 2014) and “Thermal Analysis of High-Power Flip-Chip-Bonded Photodiodes,” by Shen et al. (J. Light. Technol., Vol. 35, No. 19, October 2017)), failed to recognize that in the conventional CC-MUTC epitaxial configuration there was a significant heat flow into the InP semi-insulating substrate, rather than directly into the heat sink. Instead, it had been assumed (see, e.g., “Thermal Analysis of High-Power Flip-Chip-Bonded Photodiodes”) that the primary power handling limitation was the metal to high-thermal conductivity substrate interface. As discussed herein, the present inventors recognized that certain assumptions regarding heat flow in a CC-MUTC were incorrect, and that significant heat transfer to the heat sink was being blocked during operation of the CC-MUTC (see analysis published by the inventors, “Thermal Dissipation Enhancement in Flip-Chip Bonded Uni-Traveling carrier Photodiodes”).

Thus, the present application discloses an improved restructuring of the epitaxy of a CC-MUTC photodiode such that the absorber layer is disposed at the bottom of the epitaxial stack, where it still acts as a thermal barrier to the InP semi-insulating photodiode handle substrate, but does not act as a thermal barrier between the majority of the generated heat and the high-thermal conductivity submount substrate. In this way, the heat flow can be vastly improved to efficiently transfer the generated heat to submount materials having significantly higher thermal conductivity than InP. The high-thermal conductivity submount substrate may be formed of a material having a relatively high thermal conductivity that is greater than that of InP. Preferably the thermal conductivity of the high-thermal conductivity submount substrate is at least 150 W/mK (Watts per meter per Kelvin) such as greater than 300 W/mK, and may be greater than 1000W/mK. The high-thermal conductivity submount substrate may be formed of, for example, silicon (Si), aluminum nitride (AlN), diamond, silicon carbide (SiC), graphene, boron arsenide, Beryllium oxide or a combination of these materials.

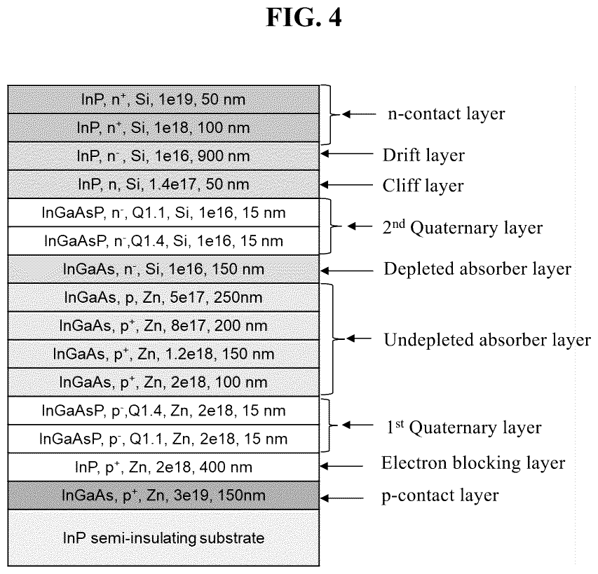

This modification to the epitaxial structure is referred to herein as a flipped CC-MUTC epitaxy. Examples of flipped CC-MUTC epitaxy disclosed herein are illustrated in FIGS. 4, 7, and 8.

FIG. 4 illustrates a flipped CC-MUTC epitaxial structure comprising a semiconductor substrate having a stack of functional layers formed thereon, the stack of functional layers comprising a p-contact layer, an undepleted absorber layer, a depleted absorber layer, a cliff layer, a drift layer, and an n-contact layer sequentially stacked on the semiconductor substrate. A stack of functional layers may also be referred to herein simply as a/the stack or mesa. The CC-MUTC is thermally limited, where its ability to operate at high power levels is only limited in its ability to withstand heat (i.e., high temperature is the cause of failure), and thus removal of heat is a key factor in high power operation. In contrast, many photodiodes are limited by a space-charge effect, where operational power is limited due to the collapse of the electric field. In a CC-MUTC, there is no electric field collapse (an electric field collapse does limit its operational power) that cannot be overcome with the application of higher bias voltage. In a CC-MUTC, only electrons traverse the drift region to contribute to the photocurrent produced by the CC-MUTC.

In example embodiments, the functional layers of the CC-MUTC may be sequentially grown on the semiconductor substrate by metal-organic chemical vapor deposition beginning with the p-contact layer and continuing sequentially with the undepleted absorber layer, the depleted absorber layer, the cliff layer, the drift layer, and the n-contact layer. FIG. 4 illustrates, for each of the layers (or component layers thereof), the intrinsic semiconductor material of the layer, the dopant type (and relative concentration), the dopant material and the concentration (atoms per cubic cm) of the dopant, and the thickness of the layer. Thickness may refer to the thickness or height measured in a direction perpendicular to the top surface of the semiconductor substrate and/or perpendicular to the major extending directions of a layer.

For example, the electron blocking layer is denoted with “InP, p+, Zn, 2e18, 100 nm” indicating the electron blocking layer is formed of a 100 nm layer of InP, doped with a p-type dopant of Zn at a concentration of 2.0×10\hat{ }18 atoms per cubic cm. As is conventional, “p+” indicates a relatively higher dopant/carrier concentration with respect to dopants identified as “p” or “p−” (where “p” indicates a higher dopant/carrier concentration relative to “p−”). It will be appreciated that the details of these layers are just examples. The layers may be formed with different semiconductor materials, dopants, and concentrations thereof while maintaining relative dopant concentrations to obtain desired junction voltage, maximum crystal lattice differences (i.e., to avoid large crystal lattice constant differences between adjacent layers), or other desired results.

The semiconductor substrate may be an InP semi-insulating substrate and may be a crystalline semiconductor InP (indium phosphide) wafer lightly doped with a charge carrier dopant, such as with a p-type (acceptor) impurity (e.g., Fe (iron) or Zn (zinc)) or with both n-type (donor) (e.g., Si (silicon) or Te (tellurium)) and p-type impurities. As illustrated in FIG. 4, a quaternary compound (e.g., indium gallium arsenide phosphide (InGaAsP)) forming crystal lattice transition layers (i.e., quaternary layers) are disposed between the p-contact layer and the absorber layer, and are also disposed between the absorber layer and the cliff layer. The quaternary layers (e.g., InGaAsP layers) mitigate electric field discontinuities between the respectively separated layers.

In the embodiment of FIG. 4, the flipped CC-MUTC photodiode includes an InP semi-insulating substrate having a stack of functional layers including a p-contact layer comprising p+ InGaAs; an electron blocking layer comprising p+ InP; a first quaternary layer comprising p− InGaAsP; an undepleted absorber layer comprising p+ InGaAs and p InGaAs; a depleted absorber layer comprising n−InGaAs, a second quaternary layer comprising n− InGaAsP; a cliff layer comprising n InP; a drift layer comprising n− InP layer; and an n-contact layer comprising n+ InP sequentially stacked thereon. The InP layers may be transparent to the light to which the CC-MUTC is sensitive (the spectrum of light that causes the CC-MUTC generate a photocurrent), such as transparent to infrared light (e.g., transparent to light having wavelengths of 850 nm, 1310 nm and 1550 nm). In addition, InP has good thermal conductivity (especially as compared to InGaAs during high power operation of the MUTC). As conventional, “n” indicates the doping (i.e., n-type doped) of a layer with n-type charge carrier impurities (donor type) and “p” indicates the doping (i.e., p-type doped) of a semiconductor material with p-type charge carrier impurities (acceptor type) (with the “+” indicating a relatively higher concentration and the “−” indicating a relatively lower concentration). Each layer may be sequentially formed (epitaxially grown) on the InP semiconductor substrate in the order shown in FIG. 4 (i.e., from bottom to top with each additional layer being epitaxially grown on the layer below it), and each layer may be a crystalline semiconductor layer. The p-type and n-type impurities may be formed in situ during the epitaxial growth of the corresponding impurity doped semiconductor layer. The layers of the flipped CC-MUTC may be sequentially grown on the InP semi-insulating substrate by metal-organic chemical vapor deposition beginning with the p-contact layer and continuing sequentially with the electron blocking layer, the first quaternary layer, the undepleted absorber layer, the depleted absorber layer, the second quaternary layer, the cliff layer, the drift layer, and the n-contact layer. The p-contact layer may contact the InP semi-insulating substrate. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting,” “in contact with,” or “contact” another element, there are no intervening elements present at the point of contact.

FIG. 4 further illustrates example thicknesses and doping concentrations for the layers of the flipped CC-MUTC photodiode. For example, the p-contact layer comprising p+ InGaAs may have a thickness of about 150 nm. The electron blocking layer comprising p+ InP may have a thickness of about 400 nm. The first quaternary layer comprising p− InGaAsP may include two layers of p− InGaAsP, each having a thickness of about 15 nm. The undepleted absorber layer may include a first layer of p+ InGaAs having a thickness of 100 nm, a second layer of p+ InGaAs having a thickness of about 150 nm, a third layer of p+ InGaAs having a thickness of about 200 nm, and a fourth layer of p InGaAs having a thickness of about 250 nm. The depleted absorber layer comprising n− InGaAs may have a thickness of about 150 nm. To facilitate electron transport, the absorber layer is partially depleted and the doping levels graded to achieve a quasi-electric field which aids in electron transport.

The second quaternary layer comprising n− InGaAsP may include two layers of n− InGaAsP, each having a thickness of about 15 nm. The cliff layer comprising n InP may have a thickness of about 50 nm. The drift layer comprising n− InP may have a thickness of about 900 nm. The n-contact layer comprising n+ InP may include two layers of n+ InP, wherein the first layer may have a thickness of about 100 nm and the second layer may have a thickness of about 50 nm. Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

As illustrated in FIG. 4, the cliff layer is disposed at the heterojunction interface between InP (e.g., the drift layer) and InGaAsP (e.g., the quaternary layer) or, more generally, between the InP (e.g., the drift layer) and InGaAs (e.g., the absorber layer). In comparison to the layers that surround the cliff layer on both sides (i.e., the layers above and below the cliff layer), the cliff layer will have a relative higher p-doping. This higher doping raises the bandgap of InP to bring it closer to that of the InGaAsP and, more generally, to that of InGaAs. As such, the cliff layer is a highly doped layer at the heterojunction interface between the InGaAs (e.g., absorber layer) and InP (e.g.,. drift layer), or more specifically, the cliff layer is a highly doped layer at the heterojunction interface between the InGaAsP (e.g., the quaternary layer) and InP (e.g., the drift layer). The cliff layer thereby performs the function of smoothing the bandgap transition/electric field at this heterojunction interface—which ultimately leads to less saturation and higher power output.

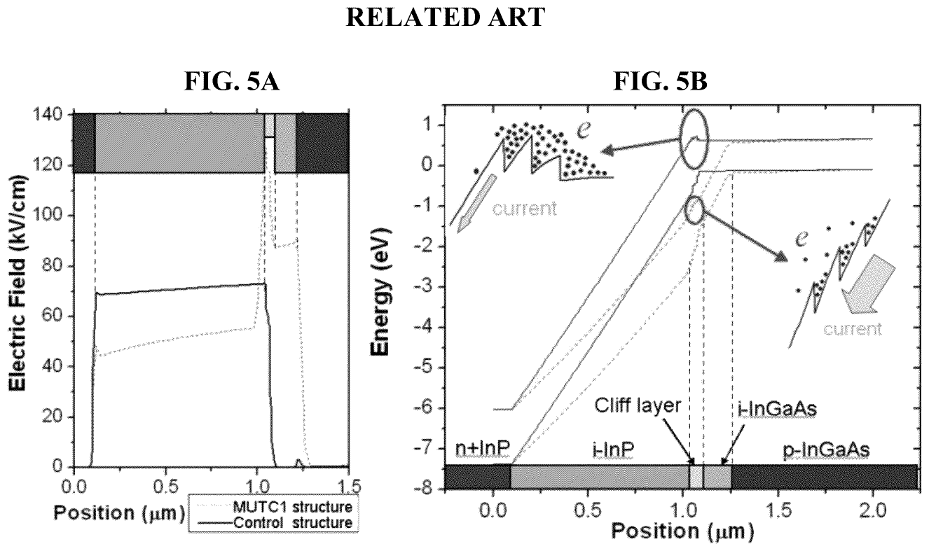

This function of smoothing the bandgap transition/electric field as performed by the cliff layer is further illustrated in FIGS. 5A and 5B. For example, FIG. 5A illustrates the internal electric fields and FIG. 5B illustrates the band diagram of a MUTC with a cliff layer and a MUTC without a cliff layer (i.e., “control structure”). Specifically, FIG. 5A shows the electric field of the MUTC with the cliff layer included (dotted line) and the electric field in the control structure (solid line), and FIG. 5B shows the bandgap (i.e., energy gap) within the MUTC with the cliff layer included (dotted line) and the bandgap (i.e., energy gap) within the control structure (solid line). As illustrated in the enlarged portion of FIG. 5B with respect to the control structure (solid line), without the cliff layer the bandgap is flat and jagged. Flat indicates the electric field within this region does not act to move electrons through the device. The jagged bandgap includes “local minimums” where the electrons may be trapped where eventually they may recombine (with a hole) and not contribute to the photocurrent produced by the photodetector. As illustrated in the enlarged portion of FIG. 5B with respect to the MUTC with the cliff layer, this region of the plot is “smoothed.” When this same region is compared to the charted electric field of the control structure in FIG. 5A the electric field in the absorber is essentially zero for the control structure, while the MUTC with the cliff layer has an increased electric field. (See, e.g., Huapu Pan, “High-Power High-Linearity Photodiodes and High-Power Photodiodes as Optoelectronic Mixers” (dissertation presented to School of Engineering and Applied Science, University of Virginia, August 2010)).

The flipped CC-MUTC epitaxy disclosed herein is novel and non-obvious for several reasons. As shown in FIG. 1, conventional CC-MUTC epitaxy, in contrast with the flipped CC-MUTC epitaxy disclosed in FIG. 4, do not use an InP n-contact layer at the top of the epitaxial structure. One reason for this is that an InP n-contact layer has a lower contact resistance than a p−InGaAs contact. As a result, conventional CC-MUTC epitaxy utilize a p−InGaAs contact at the top of the epitaxial wafer (i.e., opposite of the InP semiconductor substrate). The contact at the bottom of the epitaxial structure forming the CC-MUTC (i.e., the contact formed on the InP substrate below the remaining layers of epitaxial structure) has a longer current path to transport charge to the metal electrodes—i.e., a current path through the bottom electrode that includes a horizontal distance from the center of the stack to the metal electrodes. Thus, if the p−InGaAs contact of a conventional CC-MUTC (having significantly higher contact resistance than the n−InP contact) were provided at the bottom of the stack (e.g., in contact with the InP substrate), the series resistance (or bulk resistance) of the entire CC-MUTC would undesirably increase, such as up to about 100 times. Even with modifications by the present inventors to address such high contact resistance, the resulting series resistance was still significantly increased by 10× or more. However, by organizing the stack of functional layers such that the depleted absorber layer is not interposed between the drift layer and the high thermal conductivity submount, heat generated by the drift layer is not blocked by the depleted absorber layer. As such, heat may be more efficiently removed from the CC-MUTC, and thus the thermal limitations of the CC-MUTC may be more effectively addressed to allow for higher operational power. As a photodiode bandwidth is inversely proportional to its active area, it also implies that flipping the absorber may only be beneficial up to a yet to be determined theoretical frequency.

Another reason demonstrating novelty and non-obvious of the flipped CC-MUTC epitaxy disclosed herein is that the flipping of the absorber may only be beneficial within a specific regime of heat generation, as shown in FIG. 3. For this simulation, which assumes a total contact resistance of 2.5 Ω, the majority of the heat is only generated within the intrinsic region at photocurrents greater than 20 mA. While this is only a first-order estimate, the implication is clear that there is some crossover point in photocurrent where the flipped epitaxy will have significantly improved thermal performance compared to the original design which to this point had not been previously factored into how the epitaxy is vertically oriented.

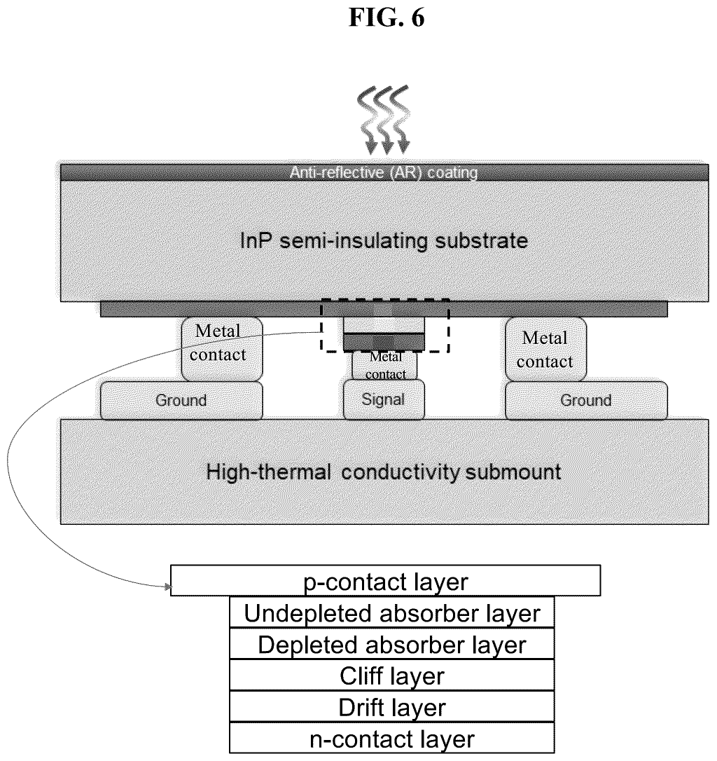

Another reason demonstrating novelty and non-obvious of the flipped CC-MUTC epitaxy disclosed herein is that using the flipped CC-MUTC epitaxy, it is difficult to achieve good electrical contact to the p-contact layer without negatively impacting device performance. This concept is illustrated using a variation of the flipped absorber CC-MUTC structure shown in FIG. 4 in the flip-bonded structure illustrated in FIG. 6. Using InGaAs p-contact, now at the bottom of the mesa structure, optical coupling efficiency may be significantly reduced. This is because InGaAs of this type will be absorptive at infrared wavelengths (e.g., absorptive to light having wavelengths of 850 nm, 1310 nm and 1550 nm, typically used in telecom) and below. Any light absorbed in this layer will also not contribute to the total photocurrent. Therefore, it is desirable to keep this layer thin. On the other hand, making this layer too thin will add to the series resistance of the photodetector, which will also reduce device performance. These implied tradeoffs make it challenging to implement the flipped absorber epitaxy disclosed herein, which is why all CC-MUTC epitaxies thus far investigated have used the traditional absorber-drift layer arrangement.

Additionally, as demonstrated in contrasting FIGS. 1 and 4, the flipped CC-MUTC epitaxy disclosed in FIG. 4 does not include layers of InGaAs and highly doped InP located proximal to the InP semi-insulating substrate. As noted above, InGaAs has a very low thermal conductivity, and thus its removal anywhere in the structure will improve heat flow. Furthermore, the complete removal of a highly doped InP layer, and the significant reduction in thickness of the InP n-contact layer is motivated by the fact that doped InP has reduced thermal conductivity compared to intrinsic InP, and while InP has a higher thermal conductivity than InGaAs, compared to most metal and non-conducting flip-chip bonding substrates of interest, its thermal conductivity is significantly lower, as shown in Table 1. Thus the removal or modification of all these epitaxial layers is required for optimum performance.

FIG. 6 illustrates a cross-sectional view of a flip-bonded structure utilizing the flipped CC-photodiode illustrated in FIG. 4. As illustrated in FIG. 6, the flipped CC-MUTC photodiode has been flipped such that the n-contact layer faces a heat sink (e.g., a high-thermal-conductivity submount substrate, such as a diamond or SiC submount substrate) and the flipped CC-MUTC photodiode is then bonded to the heat sink. As illustrated in FIG. 6, the bonded structure is in the form of a mesa structure with an anti-reflecting (AR) coating formed on the InP semi-insulating substrate. The bonding may be implemented via metal (e.g., titanium (Ti), gold (Au)) contacts. The bonding may also be based on the formation of high-thermal conductivity gold-gold thermo-compression bonds as connectors between electrodes (e.g., pads) patterned on both the flipped CC-MUTC photodiode and the high-thermal-conductivity submount.

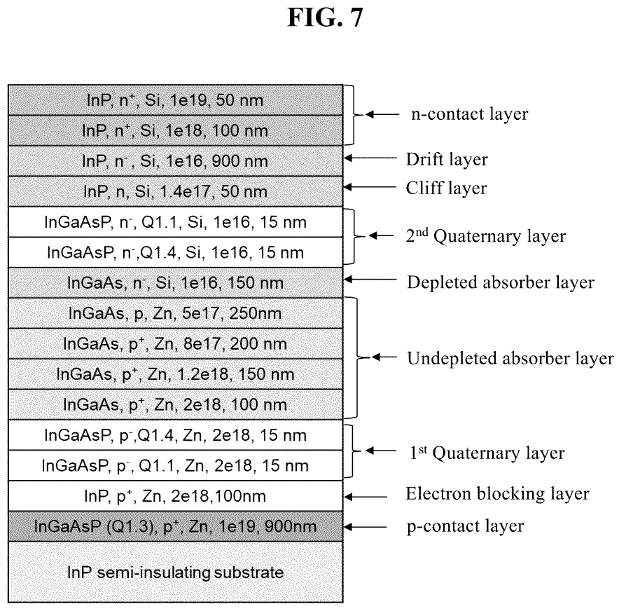

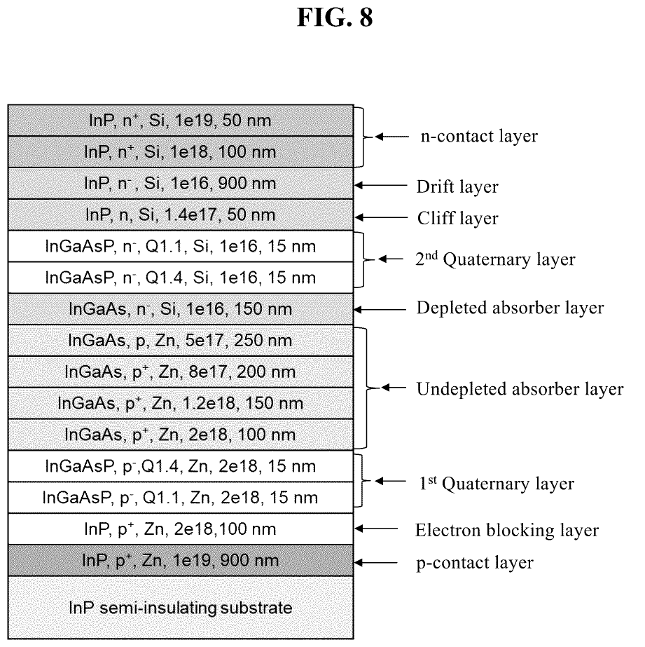

FIGS. 7 and 8 each illustrate alternate embodiments to a flipped CC-MUTC epitaxy disclosed herein. For brevity of explanation, a detailed description of technical features the same as those of the flipped CC-MUTC epitaxy disclosed in FIG. 4 and discussed above may be omitted, and a difference thereof will be described.

Referring to FIG. 7, a flipped CC-MUTC epitaxy including a p-contact layer having a greater thickness than the p-contact layer included in the flipped CC-MUTC epitaxy disclosed in FIG. 4 may be provided. For example, as illustrated in FIG. 7, the flipped CC-MUTC epitaxy may include a p-contact layer comprising p+ InGaAsP and having a thickness of about 900 nm. In this case, optical efficiency would be improved at optical wavelengths above the cutoff of InGaAsP. However, depositing InGaAsP of sufficient doping concentration to achieve low contact resistance is difficult—because of this a thicker layer of InGaAsP is required than for InGaAs. Moreover, due to the very low thermal conductivity of InGaAsP (see Table 1), this embodiment of the flipped CC-MUTC epitaxy will have, in comparison to the embodiment disclosed in FIG. 4, a reduced thermal performance.

Referring to FIG. 8, a flipped CC-MUTC epitaxy including a p-contact layer comprising p+ InP may be provided. InP is optically transparent at telecom wavelengths (i.e., infrared), and thus this embodiment will not reduce optical coupling efficiency. Furthermore, any excess layers of InGaAs/InGaAsP which reduce heat flow have been removed. However, it may be difficult to achieve an InP p-contact layer of sufficient doping concentration to achieve low series resistance. The p-contact layer may benefit from being patterned very close to the photodetector functional stack (mesa). In addition, high-temperature anneals may be beneficial to improve series resistance.

While the flipped CC-MUTC epitaxy shown in FIGS. 4, 7, and 8 may prove to be high-performance design choices, each suffers from inherent performance tradeoffs and/or fabrication difficulties which are not present in the traditional design.

This concept of flipping the low-thermal conductivity absorber may be applied to photodiode epitaxies other than conventional CC-MUTC epitaxy. This includes, but is not limited to, slight modifications to conventional CC-MUTC epitaxy to support higher frequency operation. These designs may reduce the layer thicknesses of the absorber and drift regions of the photodiode to support broadband performance at high frequencies, such as 40 GHz or more, 60 GHz or more, or even greater than 100 GHz (these frequencies representing the RF frequencies of the photocurrent the CC-MUTC is able to generate). While all these photodiode structures are based on optical back-illumination, which supports flip-chip bonding, it is also possible to leverage the flipped absorber structure within a waveguide configuration of a CC-MUTC analog. The flipped absorber concept can also be easily applied to alternative photodiode designs based on other low-thermal conductivity absorber materials, including InGaAsP, AlInAs, AlInAsSb, etc, which may include UTC photodiode designs. The flipped absorber concept may be applied to the photodiodes and thermally conductive submounts and manufacturing methods described in U.S. Pat. No. 10,686,084, the entire contents of which are hereby incorporated by reference (e.g., with the stack of functional layers of the photodiode device provided with respect to the thermally conductive submount as described herein).

Finally, the benefit of the flipped absorber methodology is not limited to high-power RF generation. Improvements in gain stability, non-linearity, environmental robustness, and other figures of merit which are affected by the distribution of heat throughout the photodiode structure may also be achievable by leveraging our concept.

What is claimed is:

1. A charge-compensated modified uni-traveling carrier (CC-MUTC) photodiode comprising:
a semiconductor substrate;
a stack of functional layers including:
a p-contact layer stacked on and in contact with the semiconductor substrate;
an absorber layer stacked on the p-contact layer;
a cliff layer stacked on the absorber layer;
a drift layer stacked on the cliff layer;
an n-contact layer stacked on the drift layer;
a first metal contact in contact with the p-contact layer; and
a second metal contact in contact with the n-contact layer.

2. The CC-MUTC photodiode of claim 1, wherein the absorber layer comprises a plurality of layers including at least one undepleted absorber layer and at least one depleted absorber layer.

3. The CC-MUTC photodiode of claim 2, wherein the at least one undepleted absorber layer includes a p-type doped InGaAs layer and the at least one depleted absorber layer includes an n-type doped InGaAs layer.

4. The CC-MUTC photodiode of claim 3, wherein the concentration of doping in the absorber layer is different among the different layers of the absorber layer.

5. The CC-MUTC photodiode of claim 3, wherein the concentration of doping in the depleted absorber layer is less than the concentration of doping in the undepleted absorber layer.

6. The CC-MUTC photodiode of claim 3, wherein the cliff layer includes an n-type doped InP layer.

7. The CC-MUTC photodiode of claim 6, wherein the drift layer includes an n-type doped InP layer.

8. The CC-MUTC photodiode of claim 7, wherein the cliff layer is disposed between the drift layer and the absorber layer.

9. The CC-MUTC photodiode of claim 8, wherein the concentration of doping in the cliff layer is less than the concentration of doping in the drift layer and the concentration of doping in the absorber layer.

10. The CC-MUTC photodiode of claim 1, further comprising:
a first quaternary layer disposed between the p-contact layer and the absorber layer; and
a second quaternary layer disposed between the absorber layer and the cliff layer.

11. The CC-MUTC photodiode of claim 1, wherein the p-contact layer has a thickness of 150 nm.

12. The CC-MUTC photodiode of claim 1, wherein the p-contact layer has a thickness of 900 nm.

13. The CC-MUTC photodiode of claim 1, wherein the p-contact layer is a p-type InGaAs layer.

14. The CC-MUTC photodiode of claim 1, wherein the p-contact layer is a p-type InP layer.

15. A flip-chip bonded charge-compensated modified uni-traveling carrier (CC-MUTC) photodiode comprising:
a semiconductor substrate;
a stack of functional layers, including:
a p-contact layer stacked on and in contact with the semiconductor substrate;
an absorber layer stacked on the p-contact layer;
a cliff layer stacked on the absorber layer;
a drift layer stacked on the cliff layer;
an n-contact layer stacked on the drift layer; and
a heat sink on the stack of functional layers,
wherein the n-contact layer is disposed closer to the heat sink than the p-contact layer.

16. The flip-chip bonded CC-MUTC photodiode of claim 15, wherein the heat sink is a substrate comprising a material having a thermal conductivity greater than or equal to 150 W/mK.

17. The flip-chip bonded CC-MUTC photodiode of claim 15, wherein the absorber layer comprises a plurality of layers including at least one undepleted absorber layer and at least one depleted absorber layer.

18. The flip-chip bonded CC-MUTC photodiode of claim 17, wherein the at least one undepleted absorber layer is a p-type doped InGaAs layer and the at least one depleted absorber layer us an n-type doped InGaAs layer.

19. The flip-chip bonded CC-MUTC photodiode of claim 18, wherein the concentration of doping in the absorber layer is different among the different layers of the absorber layer.

20. The CC-MUTC photodiode of claim 18, wherein the concentration of doping in the depleted absorber layer is less than the concentration of doping in the undepleted absorber layer.

21. The flip-chip bonded CC-MUTC photodiode of claim 18, wherein the cliff layer is an n-type InP layer.

22. The flip-chip bonded CC-MUTC photodiode of claim 21, wherein the drift layer is a n-type InP layer.

23. The flip-chip bonded CC-MUTC photodiode of claim 22, wherein the cliff layer is disposed between the drift layer and the absorber layer.

24. The flip-chip bonded CC-MUTC photodiode of claim 23, wherein the concentration of doping in the cliff layer is less than the concentration of doping in the drift layer and the concentration of doping in the absorber layer.

25. The flip-chip bonded CC-MUTC photodiode of claim 15, further comprising:
a first quaternary layer disposed between the p-contact layer and the absorber layer; and
a second quaternary layer disposed between the absorber layer and the cliff layer.

26. The flip-chip bonded CC-MUTC photodiode of claim 15, wherein the p-contact layer has a thickness of 150 nm.

27. The flip-chip bonded CC-MUTC photodiode of claim 15, wherein the p-contact layer has a thickness of 900 nm.

28. The flip-chip bonded CC-MUTC photodiode of claim 15, wherein the p-contact layer is a p-doped InGaAs layer.

29. The flip-chip bonded CC-MUTC photodiode of claim 15, wherein the p-contact layer is a p-doped InP layer.

30. The flip-chip bonded CC-MUTC photodiode of claim 1, wherein the first metal contact is horizontally spaced apart from the center of the stack of functional layers and the second metal contact is vertically placed on a center of the stack of functional layers.

31. The CC-MUTC photodiode of claim 1, further comprising a thermally conductive submount on the second metal contact, the thermally conductive submount having a thermal conductivity of at least 300 W/mK,
wherein the absorber layer includes an undepleted absorber layer, and
wherein the undepleted absorber layer is not interposed between the drift layer and the thermally conductive submount.

32. The CC-MUTC photodiode of claim 31, wherein the thermally conductive submount is formed of diamond or SiC.

33. The CC-MUTC photodiode of claim 1, wherein only electrons traverse the drift layer to contribute to the photocurrent of the CC-MUTC.

34. The CC-MUTC photodiode of claim 1, wherein the CC-MUTC is thermally limited such that the maximum power of the electrical signal generated by the CC-MUTC is limited only by the temperature the MUTC can withstand before its failure.

35. The CC-MUTC photodiode of claim 1, wherein the cliff layer is configured to avoid an electric field collapse across the functional layers of the CC-MUTC.

36. The CC-MUTC photodiode of claim 1, wherein the operational power of the CC-MUTC is not limited by a space-charge effect.

37. The CC-MUTC photodiode of claim 1,
wherein the functional stack is formed on a first surface of the semiconductor substrate,
wherein an anti-reflective coating is formed on a second surface of the semiconductor substrate to receive light to provide to the functional stack through the semiconductor substrate, and
wherein the p-contact layer is positioned between the anti-reflective coating and the absorber layer and the p-contact layer is absorptive to the infrared light.

38. The flip-chip bonded CC-MUTC photodiode of claim 30,
wherein a first current path extends horizontally and has a distance corresponding to a distance from the first metal contact to the center of the stack of functional layers,
wherein a second current path extends vertically and has a distance corresponding to the thickness of the n-contact layer.

39. A method of manufacturing a charge-compensated modified uni-traveling carrier (CC-MUTC) photodiode comprising:
forming a stack of functional layers onto a semiconductor substrate, the functional layers including:
a p-contact layer stacked on and in contact with the semiconductor substrate;
an absorber layer stacked on the p-contact layer;
a cliff layer stacked on the absorber layer;
a drift layer stacked on the cliff layer;
an n-contact layer stacked on the drift layer;
connecting a first metal contact to the p-contact layer; and
connecting a second metal contact to the n-contact layer.
